(19) United States
(12) Patent Application Publication
(10) Pub. No.: US 2010/0006841 A1
(43) Pub. Date: Jan. 14, 2010

(54) DUAL METAL GATE TRANSISTOR WITH RESISTOR HAVING DIELECTRIC LAYER BETWEEN METAL AND POLYSILICON

(75) Inventors: Weipeng Li, Beacon, NY (US); Chendong Zhu, Beacon, NY (US); Sri Samavedam, Fishkill, NY (US)

Correspondence Address: HOFFMAN WARNICK LLC, 75 STATE ST, 14TH FL, ALBANY, NY, 12207, US

(73) Assignees: INTERNATIONAL BUSINESS MACHINES CORPORATION, Armonk, NY (US); FREESCALE SEMICONDUCTOR INC., Austin, TX (US)

(21) Appl. No.: 12/171,733

(22) Filed: Jul. 11, 2008

(51) Int. Cl. H01L 27/06; H01L 29/04

(52) U.S. Cl. 257/52; 257/538; 257/E27.016; 257/E29.003

(57) ABSTRACT

Structures are presented including a high-k and metal gate transistor and a resistor where the resistor includes a dielectric layer between a metal and a polysilicon. The resistor provides typical polysilicon resistor performance with less cost and higher throughput.

### BACKGROUND

1. Technical Field

The disclosure relates generally to integrated circuit (IC) chip fabrication, and more particularly, to structures including a dual metal gate transistor and resistor.

2. Background Art

In order to continue miniaturization of integrated circuit (IC) chip technology, high dielectric constant (high-k) material and metal gate structures (i.e., dual metal gates) are replacing polysilicon and silicon oxide gate structures. Metals used in the dual metal gates such as titanium nitride (TiN) impact the performance of the resistors on the same chip. For example, the metals lower the sheet resistance and make the current-voltage non-linear.

### SUMMARY

Structures are presented including a high-k and metal gate transistor and a resistor where the resistor includes a dielectric layer between a metal and a polysilicon. The resistor provides typical polysilicon resistor performance with less cost and higher throughput.

A first aspect of the disclosure provides a structure comprising: a transistor and a resistor on the same chip, the transistor and the resistor each including a high-dielectric constant (high-k) material, a metal over the high-k material and a polysilicon over the metal; wherein the resistor further includes a dielectric layer between the metal and the polysilicon.

A second aspect of the disclosure provides a structure comprising: a transistor including a high-dielectric constant (high-k) material, a metal over the high-k material, an amorphous silicon layer over the metal and a polysilicon over the amorphous silicon layer; and a resistor on the same chip as the transistor, the resistor including the high-dielectric constant (high-k) material, the metal over the high-k material, the amorphous silicon layer over the metal, a dielectric layer over the amorphous silicon layer and a polysilicon over the dielectric layer.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a first embodiment of a structure according to the disclosure.

FIG. 2 shows a second embodiment of a structure according to the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

For high dielectric constant (high-k) and metal gate transistors, titanium nitride (TiN) or another metal is used between the high-k dielectric and polysilicon to avoid fermi level pinning between the high-k dielectric and polysilicon. A resistor is typically used to provide precise resistance for the traditional polysilicon and silicon oxide or silicon oxynitride gate technology. The metal of the high-k and metal gate transistors, however, lowers the sheet resistance of these resistors. Current approaches to address this situation include etching the amorphous silicon (Si) and metal away from the resistor. This process however is higher cost and reduces throughput.

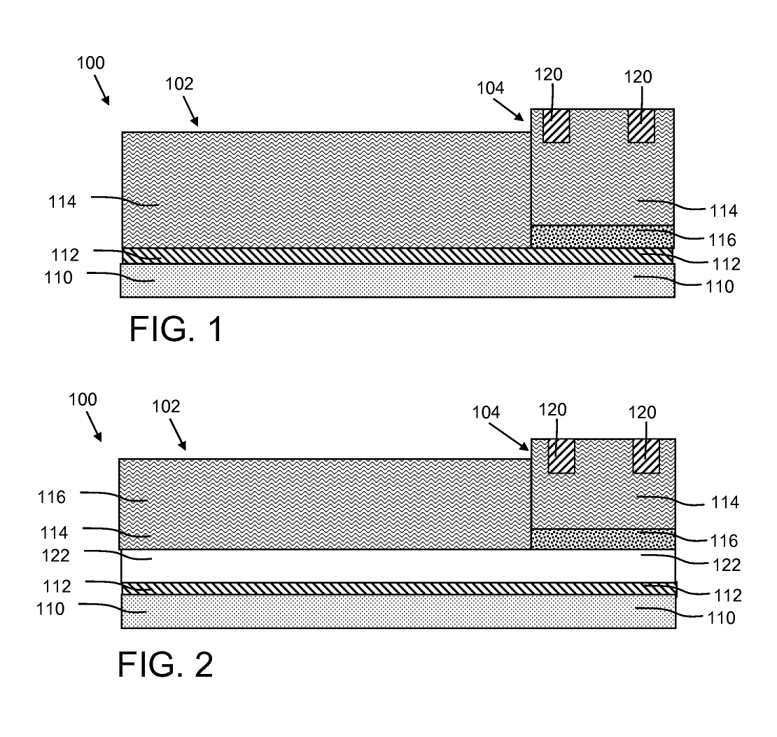

FIG. 1 illustrates one embodiment of a structure 100 including a transistor 102 and a resistor 104 on the same chip. Transistor 102 includes a high-dielectric constant (high-k) material 110, a metal 112 over high-k material 110 and a polysilicon 114 over metal 112. High-k material 110 may include but are not limited to metal oxides such as Ta₂O₅, BaTiO₃, HfO₂, ZrO₂, Al₂O₃, or metal silicates such as Hf_{A1}SiA₂O_{A3} or Hf_{A1}Si_{A2}O_{A3}N_{A4}, where A1, A2, A3, and A4 represent relative proportions, each greater than or equal to zero and A1+A2+A3+A4 (1 being the total relative mole quantity). Metal 112 may include but is not limited to titanium nitride (TiN), tantalum nitride (TaN), titanium aluminum nitride (TiAlN) or tantalum carbide (TaC). Polysilicon 114 may include a dopant to make transistor 102 and/or resistor 104 n-type or p-type. In an alternative embodiment, polysilicon 114 may be replaced by an amorphous silicon.

In contrast to conventional resistors, however, resistor 104 includes a dielectric layer 116 between metal 112 and polysilicon 114. Dielectric layer 116 may include, but is not limited to: silicon nitride (Si₃N₄), silicon oxide (SiO₂), hafnium oxide (HfO₂) or zirconium oxide (ZrO₂).

Resistor 104 may also include silicide electrodes 120. Silicide may be formed using any now known or later developed technique, e.g., depositing a metal such as titanium, nickel, cobalt, etc., annealing to have the metal react with silicon, and removing unreacted metal.

FIG. 2 shows another embodiment of a structure 200 substantially similar to structure 100 in FIG. 1. In this embodiment, however, an amorphous silicon layer 122 is also provided between metal 110 and polysilicon 114 in transistor 102 and between metal 110 and dielectric layer 116 in resistor 102.

The above-described structures 100, 200 may be formed using any now known or later developed techniques, e.g., deposition, photolithography using a resist, patterning and etching. The thickness of the dielectric layer can be in the range of approximately 200 Angstroms.

The structures as described above are used in integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a transistor and a resistor on the same chip, the transistor and the resistor each including a high-dielectric constant (high-k) material, a metal over the high-k material and a polysilicon over the metal;
wherein the resistor further includes a dielectric layer between the metal and the polysilicon.

2. The structure of claim 1, wherein the dielectric layer is selected from the group consisting of: silicon nitride (Si₃N₄), silicon oxide (SiO₂), hafnium oxide (HfO₂) and zirconium oxide (ZrO₂).

3. The structure of claim 1, wherein the metal is selected from the group consisting of: titanium nitride (TiN), tantalum nitride (TaN), titanium aluminum nitride (TiAlN) and tantalum carbide (TaC).

4. The structure of claim 1, further comprising an amorphous silicon layer between the metal and the polysilicon in the transistor and between the metal and the dielectric layer in the resistor.

5. A structure comprising:
a transistor including a high-dielectric constant (high-k) material, a metal over the high-k material, an amorphous silicon layer over the metal and a polysilicon over the amorphous silicon layer; and
a resistor on the same chip as the transistor, the resistor including the high-dielectric constant (high-k) material, the metal over the high-k material, the amorphous silicon layer over the metal, a dielectric layer over the amorphous silicon layer and a polysilicon over the dielectric layer.

6. The structure of claim 5, wherein the dielectric layer is selected from the group consisting of: silicon nitride (Si₃N₄), silicon oxide (SiO₂), hafnium oxide (HfO₂) and zirconium oxide (ZrO₂).

7. The structure of claim 5, wherein the metal is selected from the group consisting of: titanium nitride (TiN), tantalum nitride (TaN), titanium aluminum nitride (TiAlN) and tantalum carbide (TaC).
